(19) United States
(12) Patent Application Publication
(10) Pub. No.: US 2023/0215982 A1
(43) Pub. Date: Jul. 6, 2023

(54) DISPLAY DEVICE INCLUDING SEMICONDUCTOR LIGHT EMITTING DEVICE

(71) Applicants: LG ELECTRONICS INC., Seoul (KR); LG Display Co., Ltd., Seoul (KR)

(72) Inventors: Sunyong SONG, Seoul (KR); Wonseok CHOI, Seoul (KR); Jeonghyo KWON, Seoul (KR); Junoh SHIN, Seoul (KR); Youngdo KIM, Seoul (KR)

(73) Assignees: LG ELECTRONICS INC., Seoul (KR); LG Display Co., Ltd., Seoul (KR)

(21) Appl. No.: 18/093,700

(22) Filed: Jan. 5, 2023

(30) Foreign Application Priority Data
Jan. 6, 2022 (WO) PCT/KR2022/000233

(51) Int. Cl. H01L 33/38; H01L 33/62

(52) U.S. Cl. CPC H01L 33/382; H01L 33/62

(57) ABSTRACT

Discussed is a display device including a semiconductor light emitting device. A display device can include a substrate, first assembly electrodes, second assembly electrodes and the first assembly electrodes spaced apart from each other on the substrate, an insulating layer disposed on the second assembly electrode, an assembly barrier wall including a predetermined assembly hole and disposed on the insulating layer, a plating layer electrically connected to the first assembly electrode and the second assembly electrode, and a semiconductor light emitting device disposed in the assembly hole and electrically connected to the first assembly electrode and the second assembly electrode by the plating layer.

### CROSS-REFERENCE TO RELATED APPLICATION

Pursuant to 35 U.S.C. § 119(a), this application claims the benefit of an earlier filing date of and the right of priority to PCT Application No. PCT/KR2022/000233, filed in the Republic of Korea on Jan. 6, 2022, the entire contents of which are hereby expressly incorporated by reference into the present application.

### BACKGROUND OF THE DISCLOSURE

### 1. Field of the Disclosure

Embodiment relates to a display device of a semiconductor light emitting device.

### 2. Discussion of the Related Art

Large-area displays include liquid crystal displays (LCD), OLED displays, and micro-LED displays.

A micro-LED display is a display using a micro-LED, which is a semiconductor light emitting device having a diameter or cross-sectional area of 100 µm or less, as a display device.

Micro-LED display uses micro-LED, which is a semiconductor light emitting device, as a display device. Therefore, Micro-LED display uses micro-LED has excellent performance in many characteristics such as contrast ratio, response speed, color gamut, viewing angle, brightness, resolution, lifespan, luminous efficiency and luminance.

In particular, micro-LED displays have the advantage of being able to separate and combine screens in a modular way, so that size or resolution can be freely adjusted and flexible displays can be implemented.

However, since large-sized micro-LED displays require millions of micro-LEDs, there is a technical problem in that it is difficult to quickly and accurately transfer micro-LEDs to a display panel.

Transfer technologies that have been recently developed include a pick and place process, a laser lift-off method, or a self-assembly method.

Among these, the self-assembly method is a method in which the semiconductor light emitting device finds an assembly position in a fluid and is advantageous for realization of a large-screen display device.

Recently, although a micro-LED structure suitable for self-assembly has been proposed in U.S. Pat. No. 9,825,202, etc., research on a technology for manufacturing a display through self-assembly of micro-LED is still insufficient.

In particular, in the case of rapidly transferring millions of semiconductor light emitting devices to a large display in the related art, although the transfer speed can be improved, there is a technical problem in that the transfer error rate can be increased, so that the transfer yield is lowered.

In the related art, a self-assembly method using dielectrophoresis (DEP) has been attempted, but the self-assembly rate is low due to the non-uniformity of the DEP force.

Meanwhile, according to the undisclosed internal technology, self-assembly requires a DEP force, but due to the difficulty of uniform control of the DEP force, there is a problem in that the semiconductor light emitting device is tilted to a different location in the assembly hole during assembly using self-assembly.

In addition, in the subsequent electrical contact process due to the tilting phenomenon of the semiconductor light emitting device, there is a problem in that the electrical contact characteristics are reduced and the lighting rate is lowered.

Therefore, according to the unpublished internal technology, DEP force is required for self-assembly, but when using the DEP force, the semiconductor light emitting device faces a technical contradiction in which electrical contact characteristics are reduced due to the leaning phenomenon.

In addition, after self-assembly in an undisclosed internal technology, a panel wiring process in which the assembly electrode and the semiconductor light emitting device are electrically connected through deposition is in progress. However, an issue of electrical contact occurs in the panel wiring process.

In addition, according to unpublished internal technology, the distribution of DEP force is strongly formed not only inside the assembly hole but also on the upper side of the assembly hole during self-assembly using the DEP force. Accordingly, there is a problem in that the semiconductor light emitting device to be assembled cannot enter the assembly hole because the semiconductor light emitting device, which is not an assembly target, blocks the entrance to the assembly hole.

### SUMMARY OF THE DISCLOSURE

One of the technical problems of the embodiment is to solve the problem of electrical contact in the panel wiring process for electrically connecting the assembly electrode and the semiconductor light emitting device.

In addition, one of the technical problems of the embodiment is to solve the problem of low self-assembly rate due to non-uniformity of DEP force in the self-assembly method using dielectrophoresis (DEP).

In addition, the distribution of DEP force is strongly formed not only inside the assembly hole but also on the upper side of the assembly hole, which causes a phenomenon in which semiconductor light emitting devices that are not to be assembled block the entrance of the assembly hole. Accordingly, one of the technical challenges of the embodiment is to prevent the occurrence of a screening effect in which a semiconductor light emitting device to be assembled does not enter an assembly hole.

The technical problems of the embodiment are not limited to those described in this item, and include those that can be understood throughout the specification.

A display device including a semiconductor light emitting device according to an embodiment can include a substrate, a first assembly electrode, a second assembly electrode spaced apart from each other on the substrate, an insulating layer disposed on the first assembly electrode and the second assembly electrode, and an assembly barrier wall including a predetermined assembly hole and disposed on the insulating layer, a plating layer electrically connected to the first assembly electrode and the second assembly electrode, and a semiconductor light emitting device disposed in the assembly hole and electrically connected to the first assembly electrode and the second assembly electrode by the plating layer.

The insulating layer can include a center insulating layer disposed on a bottom surface of the semiconductor light emitting device and an edge insulating layer disposed spaced apart from both sides of the center insulating layer.

The center insulating layer can include a recess in the insulating layer, and a first thickness of the center insulating layer can be smaller than a second thickness of the edge insulating layer.

The plating layer can include a first plating layer disposed between a bottom surface of the semiconductor light emitting device and the center insulating layer, and a second plating layer disposed between a side surface of the semiconductor light emitting device and the first and second assembly electrodes

The first plating layer can also be disposed in a recess of the insulating layer of the center insulating layer.

One end of the second plating layer is in contact with upper surfaces of the first and second assembly electrodes exposed by the center insulating layer and the edge insulating layer, another other end of the second plating layer can be in contact with the first plating layer and can be in contact with a side surface of the semiconductor light emitting device.

The semiconductor light emitting device can include a first conductivity type semiconductor layer, an active layer and a second conductivity type semiconductor layer sequentially arranged, the semiconductor light emitting device can include a protruding semiconductor layer in which a side surface of the second conductivity type semiconductor layer extends laterally than the first conductivity type semiconductor layer.

The first plating layer can also be disposed on the protruding semiconductor layer.

In addition, a display device can include a semiconductor light emitting device according to an embodiment can include a substrate, a first assembly electrode, a second assembly electrode spaced apart from each other on the substrate, an insulating layer disposed on the first assembly electrode and the second assembly electrode, and an assembly barrier wall including a predetermined assembly hole and disposed on the insulating layer, a plating layer electrically connected to the first assembly electrode and the second assembly electrode, and a semiconductor light emitting device disposed in the assembly hole and electrically connected to the first assembly electrode and the second assembly electrode by the plating layer.

The semiconductor light emitting device can include a first conductivity type semiconductor layer, an active layer and a second conductivity type semiconductor layer sequentially arranged, and the semiconductor light emitting device can include a protruding semiconductor layer in which a side surface of the second conductivity type semiconductor layer extends laterally than the first conductivity type semiconductor layer.

The plating layer can include a first plating layer disposed between the bottom surface of the semiconductor light emitting device and the center insulating layer, and a second plating layer disposed between the side surface of the semiconductor light emitting device and the first and second assembly electrodes.

The first plating layer can also be disposed on the protruding semiconductor layer.

According to the display device including the semiconductor light emitting device according to the embodiment, it is possible to solve the problem of electrical contact in the panel wiring process for electrically connecting the assembly electrode and the semiconductor light emitting device.

For example, according to the embodiment, the plating layer 240 can include a second plating layer 240b disposed between the side surface of the semiconductor light emitting device 150 and the first and second assembly electrodes 210 and 220, and electrical reliability can be improved by improving the electrical contact performance in the panel wiring process for electrically connecting the assembly electrode and the semiconductor light emitting device.

Accordingly, according to the embodiment, it is possible to reduce assembly defects by removing solder from the bottom surface of the semiconductor light emitting device chip in the internal technique, and it is possible to prevent the light emitting device chip from being separated during the metal contact process.

In addition, according to the embodiment, the plating layer 240 can include a first plating layer 240a that is disposed between the bottom surface of the semiconductor light emitting device 150 and the center insulating layer 212c, and power can be evenly applied to the entire bottom surface of the semiconductor light emitting device 150, so that there is a special technical effect that can significantly improve the luminance of the display.

In addition, according to the embodiment, the lower side of the semiconductor light emitting device 150 receives more DEP force by the protruding semiconductor layer 152P, so that there is a special technical effect of controlling the vertical direction of the semiconductor light emitting device 150.

For example, in the case of the semiconductor light emitting device 150N, which is a vertical light emitting device, it can be difficult to control the directionality of the first conductivity type semiconductor layer 152a and the second conductivity type semiconductor layer 152c. However, according to the embodiment, since the semiconductor light emitting device can include the protruding semiconductor layer 152P, and a higher DEP force is applied to the protruding semiconductor layer 152P, there is a special technical effect of controlling the direction of the second conductivity type semiconductor layer 152c to the direction of the assembly electrodes 210 and 220.

In addition, according to the embodiment, there is a technical effect that can solve the problem of low self-assembly rate due to non-uniformity of DEP force in the self-assembly method using dielectrophoresis (DEP).

In addition, the embodiment can prevent the entrance of the assembly hole from being blocked by preventing a semiconductor light emitting device, which is not an assembly target, from being located on the upper side of the assembly hole. Accordingly, the embodiment has a technical effect of significantly increasing the assembly yield by solving the problem of the screening effect in which the semiconductor light emitting device to be assembled does not enter the assembly hole and concentrating the DEP Force uniformly on the assembly hole to be assembled.

The technical effects of the embodiments are not limited to those described in this item, and include those identified from the description of the invention.

### BRIEF DESCRIPTION OF THE DRAWINGS

FIG. 1 is an exemplary view of a living room of a house in which a display device according to an embodiment is disposed.

FIG. 2 is a block diagram schematically showing a display device according to an embodiment.

FIG. 3 is a circuit diagram illustrating an example of the pixel of FIG. 2

FIG. 4 is an enlarged view of a first panel area in the display device of FIG. 1

FIG. 5 is a cross-sectional view taken along line B1-B2 of area A2 of FIG. 4

FIG. 6 is an exemplary view in which the light emitting device according to the embodiment is assembled on a substrate by a self-assembly method.

FIG. 7 is a partially enlarged view of area A3 of FIG. 6

FIGS. 8A and 8B are examples of self-assembly in the display device 300 according to the internal technology.

FIG. 8C is a self-assembly picture of the display device according to the internal technology.

FIG. 8D is a view showing a tilt phenomenon that occurs during self-assembly to the internal technology.

FIG. 8E is a FIB (focused ion beam) photograph of a light emitting device (chip) and a bonding metal in a display panel according to an internal technology.

FIG. 8F is lighting data in the display panel in the internal technology.

FIG. 9 is a cross-sectional view of a display device 301 including a semiconductor light emitting device according to an embodiment.

FIGS. 10 to 18 are cross-sectional views of a manufacturing process of a display device 301 having a semiconductor light emitting device according to an embodiment.

FIG. 19 is a cross-sectional view of a display device 301 including a semiconductor light emitting device according to an embodiment.

### DETAILED DESCRIPTION OF THE EMBODIMENTS

Hereinafter, embodiments disclosed in the present description will be described in detail with reference to the accompanying drawings. The suffixes ‘module’ and ‘part’ for components used in the following description are given or mixed in consideration of ease of specification, and do not have a meaning or role distinct from each other by themselves. In addition, the accompanying drawings are provided for easy understanding of the embodiments disclosed in the present specification, and the technical ideas disclosed in the present specification are not limited by the accompanying drawings. Further, when an element, such as a layer, region, or substrate, is referred to as being ‘on’ another component, this includes that it is directly on the other element or there can be other intermediate elements in between.

The display device described in this specification can include a digital TV, a mobile phone, a smart phone, a laptop computer, a digital broadcasting terminal, a personal digital assistant (PDA), a portable multimedia player (PMP), a navigation, a Slate PC, a Tablet PC, an Ultra-Book, a desktop computer, and the like. However, the configuration according to the embodiment described in this specification can be applied to a display capable device even if it is a new product form to be developed later.

Hereinafter, a light emitting device according to an embodiment and a display device including the light emitting device will be described.

Hereinafter, a display device of a semiconductor light emitting device according to an embodiment will be described.

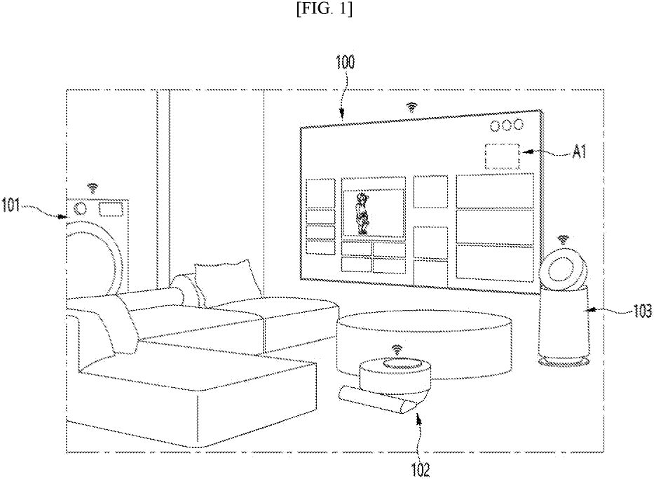

FIG. 1 shows a living room of a house in which the display device 100 according to the embodiment is disposed.

The display device 100 of the embodiment can display the status of various electronic products such as the washing machine 101, the robot cleaner 102, and the air purifier 103, and communicate with each electronic product based on IOT, and can control each electronic product based on the user’s setting data.

The display apparatus 100 according to the embodiment can include a flexible display manufactured on a thin and flexible substrate. The flexible display can be bent or rolled like paper while maintaining the characteristics of a conventional flat panel display.

In the flexible display, visual information can be implemented by independently controlling light emission of unit pixels arranged in a matrix form. A unit pixel means a minimum unit for realizing one color. The unit pixel of the flexible display can be implemented by a light emitting device. In an embodiment, the light emitting device can be a Micro-LED or a Nano-LED, but is not limited thereto.

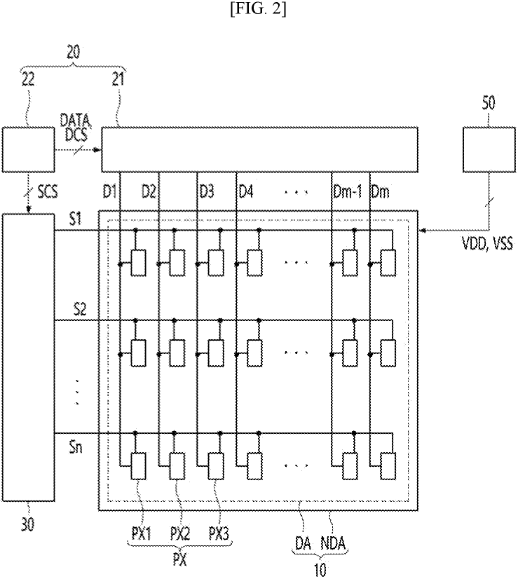

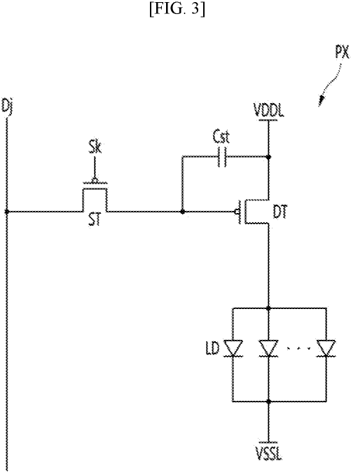

Next, FIG. 2 is a block diagram schematically showing a display device according to an embodiment, and FIG. 3 is a circuit diagram showing an example of the pixel of FIG. 2.

Referring to FIGS. 2 and 3, the display device according to the embodiment can include a display panel 10, a driving circuit 20, a scan driving unit 30, and a power supply circuit 50.

The display device 100 according to the embodiment can drive the light emitting device using an active matrix (AM) method or a passive matrix (PM, passive matrix) method.

The driving circuit 20 can include a data driving unit 21 and a timing control unit 22.

The display panel 10 can be divided into a display area DA and a non-display area NDA disposed around the display area DA. The display area DA is an area in which pixels PX are formed to display an image. The display panel 10 can include data lines (D1 to Dm, m is an integer greater than or equal to 2), scan lines crossing the data lines D1 to Dm (S1 to Sn, n is an integer greater than or equal to 2), the high-potential voltage line supplied with the high-voltage, the low-potential voltage line supplied with the low-potential voltage, and the pixels PX connected to the data lines D1 to Dm and the scan lines S1 to Sn can be included.

Each of the pixels PX can include a first sub-pixel PX1, a second sub-pixel PX2, and a third sub-pixel PX3. The first sub-pixel PX1 emits a first color light of a first wavelength, the second sub-pixel PX2 emits a second color light of a second wavelength, and the third sub-pixel PX3 emits a third color light of a wavelength can be emitted. The first color light can be red light, the second color light can be green light, and the third color light can be blue light, but is not limited thereto. Further, although it is illustrated that each of the pixels PX can include three sub-pixels in FIG. 2, the present invention is not limited thereto. For example, each of the pixels PX can include four or more sub-pixels.

Each of the first sub-pixel PX1, the second sub-pixel PX2, and the third sub-pixel PX3 can connected to at least one of the data lines D1 to Dm, and at least one of the scan lines S1 to Sn, and a high potential voltage line. As shown in FIG. 3, the first sub-pixel PX1 can include the light emitting devices LD, plurality of transistors for supplying current to the light emitting devices LD, and at least one capacitor Cst.

Each of the first sub-pixel PX1, the second sub-pixel PX2, and the third sub-pixel PX3 can include only one light emitting device LD and at least one capacitor Cst.

Each of the light emitting devices LD can be a semiconductor light emitting diode including a first electrode, a plurality of conductivity type semiconductor layers, and a second electrode. Here, the first electrode can be an anode electrode and the second electrode can be a cathode electrode, but the present invention is not limited thereto.

Referring to FIG. 3, the plurality of transistors can include a driving transistor DT for supplying current to the light emitting devices LD, and a scan transistor ST for supplying a data voltage to the gate electrode of the driving transistor DT. The driving transistor DT can include a gate electrode connected to the source electrode of the scan transistor ST, a source electrode connected to a high potential voltage line to which a high potential voltage is applied, and a drain electrode connected to first electrodes of the light emitting devices LD. The scan transistor ST can include a gate electrode connected to the scan line Sk, where k is an integer satisfying 1≤k≤n, a source electrode connected to the gate electrode of the driving transistor DT, and a drain electrode connected to data lines Dj, where j is integer satisfying 1≤j≤m.

The capacitor Cst is formed between the gate electrode and the source electrode of the driving transistor DT. The storage capacitor Cst can charge a difference between the gate voltage and the source voltage of the driving transistor DT.

The driving transistor DT and the scan transistor ST can be formed of a thin film transistor. In addition, although the driving transistor DT and the scan transistor ST have been mainly described in FIG. 3 as being formed of a P-type MOSFET (Metal Oxide Semiconductor Field Effect Transistor), the present invention is not limited thereto. The driving transistor DT and the scan transistor ST can be formed of an N-type MOSFET. In this case, the positions of the source electrode and the drain electrode of each of the driving transistor DT and the scan transistor ST can be changed.

Further, in FIG. 3 has been illustrated each of the first sub-pixel PX1, the second sub-pixel PX2, and the third sub-pixel PX3 can include one driving transistor DT, one scan transistor ST, and 2T1C (2 Transistor - 1 capacitor) having a capacitor Cst, but the present invention is not limited thereto. Each of the first sub-pixel PX1, the second sub-pixel PX2, and the third sub-pixel PX3 can include a plurality of scan transistors ST and a plurality of capacitors Cst.

Referring back to FIG. 2, the driving circuit 20 outputs signals and voltages for driving the display panel 10. To this end, the driving circuit 20 can include a data driver 21 and a timing controller 22.

The data driver 21 receives digital video data DATA and a source control signal DCS from the timing controller 22. The data driver 21 converts the digital video data DATA into analog data voltages according to the source control signal DCS and supplies them to the data lines D1 to Dm of the display panel 10.

The timing controller 22 receives digital video data DATA and timing signals from the host system. The timing signals can include a vertical sync signal, a horizontal sync signal, a data enable signal, and a dot clock. The host system can be an application processor of a smartphone or tablet PC, a monitor, or a system-on-chip of a TV.

The scan driver 30 receives the scan control signal SCS from the timing controller 22. The scan driver 30 generates scan signals according to the scan control signal SCS and supplies them to the scan lines S1 to Sn of the display panel 10. The scan driver 30 can include a plurality of transistors and can be formed in the non-display area NDA of the display panel 10. Further, the scan driver 30 can be formed of an integrated circuit, and in this case, can be mounted on a gate flexible film attached to the other side of the display panel 10.

The power supply circuit 50 generates a high potential voltage VDD and a low potential voltage VSS for driving the light emitting devices LD of the display panel 10 from the main power source, and the power supply circuit can supply VDD and VSS to the high-potential voltage line and the low-potential voltage line of the display panel 10. Further, the power supply circuit 50 can generate and supply driving voltages for driving the driving circuit 20 and the scan driving unit 30 from the main power.

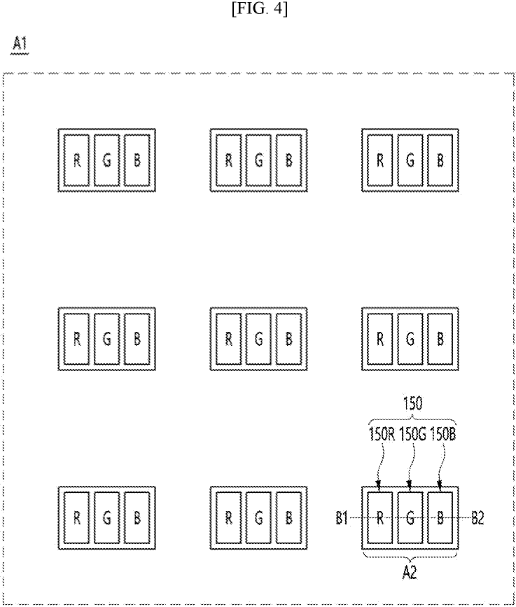

Next, FIG. 4 is an enlarged view of the first panel area A1 in the display device of FIG. 1.

Referring to FIG. 4, the display device 100 according to the embodiment can be manufactured by mechanically and electrically connecting a plurality of panel regions such as the first panel region A1 by tiling.

The first panel area A1 can include a plurality of light emitting devices 150 arranged for each unit pixel (PX in FIG. 2).

For example, the unit pixel PX can include a first sub-pixel PX1, a second sub-pixel PX2, and a third sub-pixel PX3. For example, a plurality of red light-emitting devices 150R are disposed in the first sub-pixel PX1, a plurality of green light-emitting devices 150G are disposed in the second sub-pixel PX2, and a plurality of blue light-emitting devices 150B are disposed in the third sub-pixel PX3. The unit pixel PX can further include a fourth sub-pixel in which a light emitting device is not disposed, but is not limited thereto. Meanwhile, the light emitting device 150 can be the semiconductor light emitting device.

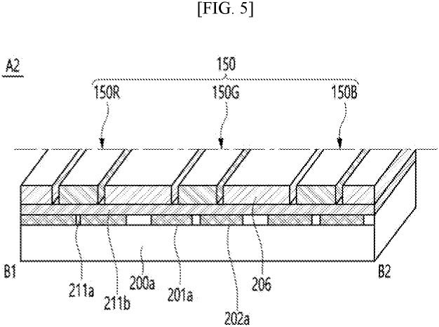

Next, FIG. 5 is a cross-sectional view taken along line B1-B2 of area A2 in FIG. 4.

Referring to FIG. 5, the display device 100 of the embodiment can include a substrate 200a, wirings 201a and 202a spaced apart from each other, a first insulating layer 211a, a second insulating layer 211b, a third insulating layer 206 and a plurality of light emitting devices 150.

The wiring can include a first wiring 201a and a second wiring 202a spaced apart from each other. The first wiring 201a and the second wiring 202a can function as panel wiring for applying power to the light emitting device 150 in the panel, and in the case of self-assembly of the light emitting device 150, Further, the first wiring 201a and the second wiring 202a can function as an assembly electrode for generating a dielectrophoresis force.

The wirings 201a and 202a can be formed of a transparent electrode (ITO) or include a metal material having excellent electrical conductivity. For example, the wirings 201a and 202a can be formed at least one of titanium (Ti), chromium (Cr), nickel (Ni), aluminum (Al), platinum (Pt), gold (Au), tungsten (W), molybdenum (Mo) or an alloy thereof.

A first insulating layer 211a can be disposed between the first wiring 201a and the second wiring 202a, and a second insulating layer 211b can be disposed on the first wiring 201a and the second wiring 202a. The first insulating layer 211a and the second insulating layer 211b can be an oxide film, a nitride film, or the like, but are not limited thereto.

The light emitting device 150 can include a red light emitting device 150R, a green light emitting device 150G , and a blue light emitting device 150B0 to form a sub-pixel, respectively, but is not limited thereto. The light emitting device 150 can include a red phosphor and a green phosphor to implement red and green, respectively.

The substrate 200a can be formed of glass or polyimide. Further, the substrate 200a can include a flexible material such as polyethylene naphthalate (PEN) or polyethylene terephthalate (PET). In addition, the substrate 200 can be made of a transparent material, but is not limited thereto. The substrate 200a can function as a support substrate in the panel, and can function as a substrate for assembly when self-assembling the light emitting device.

The third insulating layer 206 can include an insulating and flexible material such as polyimide, PEN, or PET, and can be integrally formed with the substrate 200a to form one substrate.

The third insulating layer 206 can be a conductive adhesive layer having adhesiveness and conductivity, and the conductive adhesive layer can be flexible to enable a flexible function of the display device. For example, the third insulating layer 206 can be an anisotropy conductive film (ACF) or a conductive adhesive layer such as an anisotropic conductive medium or a solution containing conductive particles. The conductive adhesive layer can be a layer that is electrically conductive in a direction perpendicular to the thickness but electrically insulating in a direction horizontal to the thickness.

The distance between the first and second wirings 201a and 202a is formed to be smaller than the width of the light emitting device 150 and the width of the assembly hole 203H, so that the assembly position of the light emitting device 150 using an electric field can be more precisely fixed.

A third insulating layer 206 is formed on the first and second wirings 201a and 202a to protect the first and second wirings 201a and 202a from the fluid 1200, and the third insulating layer 206 is can prevent leakage of current flowing through the two wirings 201a and 202a. The third insulating layer 206 can be formed of a single layer or multiple layers of an inorganic insulator such as silica or alumina or an organic insulator.

In addition, the third insulating layer 206 can include an insulating and flexible material such as polyimide, PEN, PET, etc., and can be formed integrally with the substrate 200 to form a single substrate.

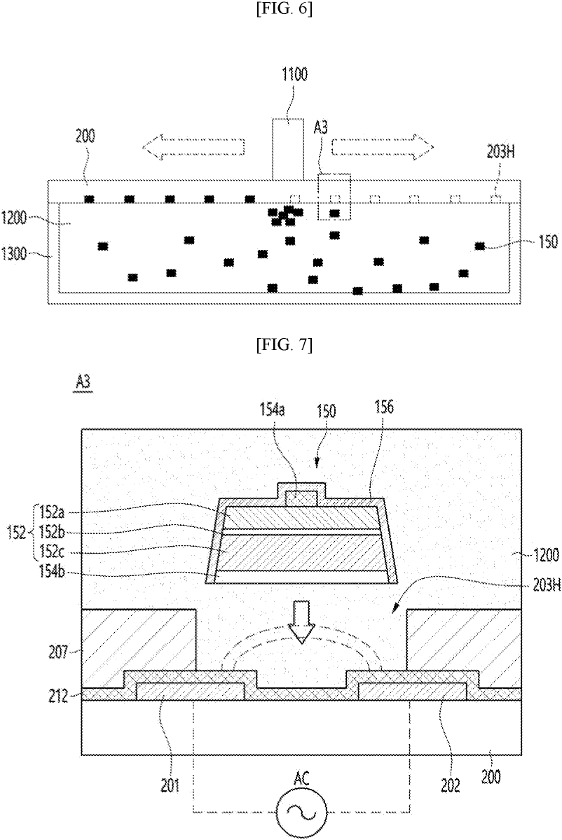

The third insulating layer 206 has a barrier wall, and an assembly hole 203H can be formed by the barrier wall. For example, the third insulating layer 206 can include an assembly hole 203H through which the light emitting device 150 is inserted (refer to FIG. 6). Accordingly, during self-assembly, the light emitting device 150 can be easily inserted into the assembly hole 203H of the third insulating layer 206. The assembly hole 203H can be referred to as an insertion hole, a fixing hole, or an alignment hole.

The assembly hole 203H can have a shape and a size corresponding to the shape of the light emitting device 150 to be assembled at a corresponding position. Accordingly, it is possible to prevent other light emitting devices from being assembled in the assembly hole 203H or from assembling a plurality of light emitting devices.

Next, FIG. 6 is a view showing an example in which the light emitting device according to the embodiment is assembled on a substrate by a self-assembly method, and FIG. 7 is a partially enlarged view of area A3 of FIG. 6. And FIG. 7 is a diagram illustrating a state in which area A3 is rotated 180 degrees for convenience of explanation.

An example in which the semiconductor light emitting device according to the embodiment is assembled in a display panel by a self-assembly method using an electromagnetic field will be described with reference to FIGS. 6 and 7.

The assembly substrate 200 to be described later can also function as the panel substrate 200a in the display device after assembly of the light emitting device, but the embodiment is not limited thereto.

Referring to FIG. 6, the semiconductor light emitting device 150 can be put into the chamber 1300 filled with the fluid 1200, and the semiconductor light emitting device 150 by the magnetic field generated from the assembly device 1100 can move to the assembly substrate 200. In this case, the light emitting device 150 adjacent to the assembly hole 203H of the assembly substrate 200 can be assembled in the assembly hole 230 by a dielectrophoretic force by an electric field of the assembly electrodes. The fluid 1200 can be water such as ultrapure water, but is not limited thereto. A chamber can be referred to as a water bath, container, vessel, or the like.

After the semiconductor light emitting device 150 is put into the chamber 1300, the assembly substrate 200 can be disposed on the chamber 1300. According to an embodiment, the assembly substrate 200 can be introduced into the chamber 1300.

Referring to FIG. 7, the semiconductor light emitting device 150 can be implemented as a vertical semiconductor light emitting device as shown, but is not limited thereto, and a horizontal light emitting device can be employed.

The semiconductor light emitting device 150 can include a magnetic layer having a magnetic material. The magnetic layer can include a magnetic metal such as nickel (Ni). Since the semiconductor light emitting device 150 injected into the fluid can include a magnetic layer, it can move to the assembly substrate 200 by the magnetic field generated from the assembly device1100. The magnetic layer can be disposed above or below or on both sides of the light emitting device.

The semiconductor light emitting device 150 can include a passivation layer 156 surrounding the top and side surfaces. The passivation layer 156 can be formed by using an inorganic insulator such as silica or alumina through PECVD, LPCVD, sputtering deposition, or the like. In addition, the passivation layer 156 can be formed through a method of spin coating an organic material such as a photoresist or a polymer material.

The semiconductor light emitting device 150 can include a structure 152 that can include a first conductivity type semiconductor layer 152a, a second conductivity type semiconductor layer 152c, and an active layer 152b disposed between the first conductivity type semiconductor layer 152a and the second conductivity type semiconductor layer 152c. The first conductivity type semiconductor layer 152a can be an n-type semiconductor layer, and the second conductivity type semiconductor layer 152c can be a p-type semiconductor layer, but is not limited thereto.

A first electrode layer 154a can be disposed on the first conductivity type semiconductor layer 152a, and a second electrode layer 154b can be disposed on the second conductivity type semiconductor layer 152c. To this end, a partial region of the first conductivity type semiconductor layer 152a or the second conductivity type semiconductor layer 152c can be exposed to the outside. Accordingly, after the semiconductor light emitting device 150 is assembled on the assembly substrate 200, a portion of the passivation layer 156 can be etched in the manufacturing process of the display device.

The assembly substrate 200 can include a pair of first assembly electrodes 201 and second assembly electrodes 202 corresponding to each of the semiconductor light emitting devices 150 to be assembled.

The first assembly electrode 201 and the second assembly electrode 202 can be formed by stacking a single metal, a metal alloy, or a metal oxide in multiple layers. For example, the first assembly electrode 201 and the second assembly electrode 202 can be formed including at least one of Cu, Ag, Ni, Cr, Ti, Al, Rh, Pd, Ir, Ru, Mg, Zn, Pt, Au, or Hf, but is not limited thereto.

In addition, the first assembly electrode 201 and the second assembly electrode 202 can be formed including at least one of indium tin oxide (ITO), indium zinc oxide (IZO), indium zinc tin oxide (IZTO), indium aluminum zinc oxide (IAZO), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), IGZO (In—Ga ZnO), ZnO, IrOx, RuOx, NiO, RuOx/ITO, Ni/IrOx/Au, or Ni/IrOx/Au/ITO, and is not limited thereto.

The first assembly electrode 201, the second assembly electrode 202 emits an electric field as an AC voltage is applied, the semiconductor light emitting device 150 inserted into the assembly hole 203H can be fixed by dielectrophoretic force. A distance between the first assembly electrode 201 and the second assembly electrode 202 can be smaller than a width of the semiconductor light emitting device 150 and a width of the assembly hole 203H, the assembly position of the semiconductor light emitting device 150 using the electric field can be more precisely fixed.

An insulating layer 212 is formed on the first assembly electrode 201 and the second assembly electrode 202 to protect the first assembly electrode 201 and the second assembly electrode 202 from the fluid 1200 and leakage of current flowing through the first assembly electrode 201 and the second assembly electrode 202 can be prevented. For example, the insulating layer 212 can be formed of a single layer or multiple layers of an inorganic insulator such as silica or alumina or an organic insulator. The insulating layer 212 can have a minimum thickness to prevent damage to the first assembly electrode 201 and the second assembly electrode 202 when the semiconductor light emitting device 150 is assembled, and it can have a maximum thickness for the semiconductor light emitting device 150 being stably assembled.

A barrier wall 207 can be formed on the insulating layer 212. A portion of the barrier wall 207 can be positioned on the first assembly electrode 201 and the second assembly electrode 202, and the remaining region can be positioned on the assembly substrate 200.

On the other hand, when the assembly substrate 200 is manufactured, a portion of the barrier walls formed on the entire upper portion of the insulating layer 212 is removed, an assembly hole 203H in which each of the semiconductor light emitting devices 150 is coupled and assembled to the assembly substrate 200 can be formed.

An assembly hole 203H to which the semiconductor light emitting devices 150 are coupled is formed in the assembly substrate 200, and a surface on which the assembly hole 203H is formed can be in contact with the fluid 1200. The assembly hole 203H can guide an accurate assembly position of the semiconductor light emitting device 150.

Meanwhile, the assembly hole 203H can have a shape and a size corresponding to the shape of the semiconductor light emitting device 150 to be assembled at a corresponding position. Accordingly, it is possible to prevent assembling other semiconductor light emitting devices or assembling a plurality of semiconductor light emitting devices in the assembly hole 203H.

Referring back to FIG. 6, after the assembly substrate 200 is disposed in the chamber, the assembly device1100 for applying a magnetic field can move along the assembly substrate 200. The assembly device 1100 can be a permanent magnet or an electromagnet.

The assembly device 1100 can move while in contact with the assembly substrate 200 in order to maximize the area applied by the magnetic field into the fluid 1200. According to an embodiment, the assembly device 1100 can include a plurality of magnetic materials or a magnetic material having a size corresponding to that of the assembly substrate 200. In this case, the moving distance of the assembly device 1100 can be limited within a predetermined range.

The semiconductor light emitting device 150 in the chamber 1300 can move toward the assembly device 1100 and the assembly substrate 200 by the magnetic field generated by the assembly device 1100.

Referring to FIG. 7, the semiconductor light emitting device 150 is moving toward the assembly device 1100, it can enter and be fixed into the assembly hole 203H by a dielectrophoretic force (DEP force) formed by the electric field of the assembly electrode of the assembly substrate.

Specifically, the first and second assembly wirings 201 and 202 can form an electric field by an AC power source, and a dielectrophoretic force can be formed between the assembly wirings 201 and 202 by this electric field. The semiconductor light emitting device 150 can be fixed to the assembly hole 203H on the assembly substrate 200 by this dielectrophoretic force.

At this time, a predetermined solder layer is formed between the light emitting device 150 and the assembly electrode assembled on the assembly hole 203H of the assembly substrate 200 to can improve the bonding force of the light emitting device 150.

In addition, a molding layer can be formed in the assembly hole 203H of the assembly substrate 200 after assembly. The molding layer can be a transparent resin or a resin including a reflective material and a scattering material.

By the self-assembly method using the electromagnetic field described above, the time required for each of the semiconductor light emitting devices to be assembled on the substrate can be rapidly reduced, so that a large-area high-pixel display can be implemented more quickly and economically.

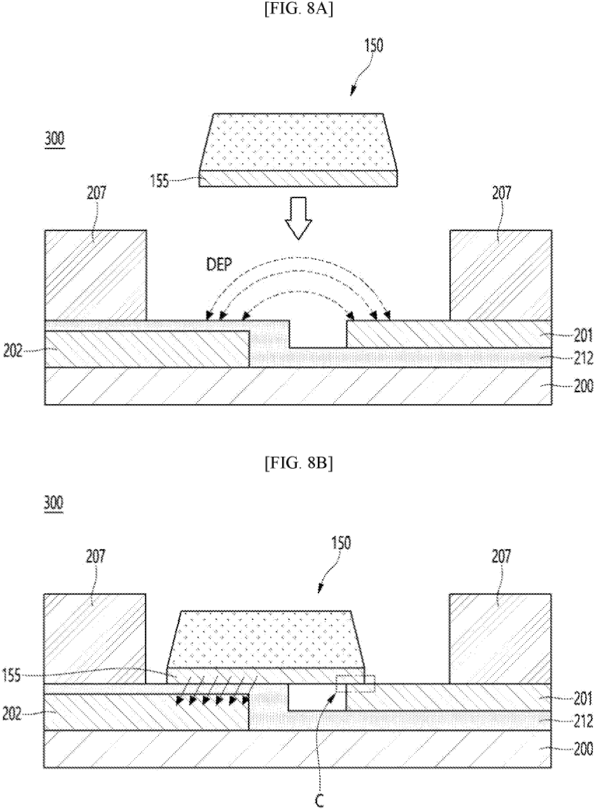

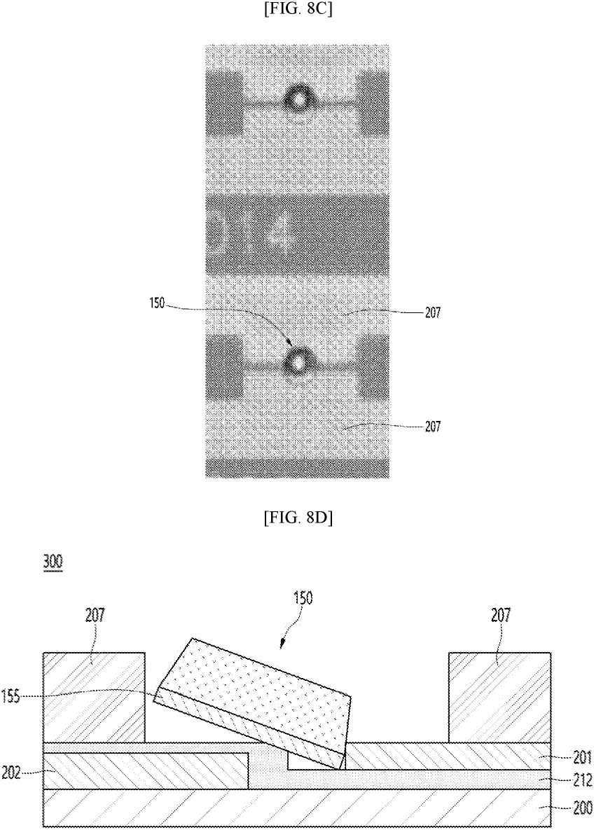

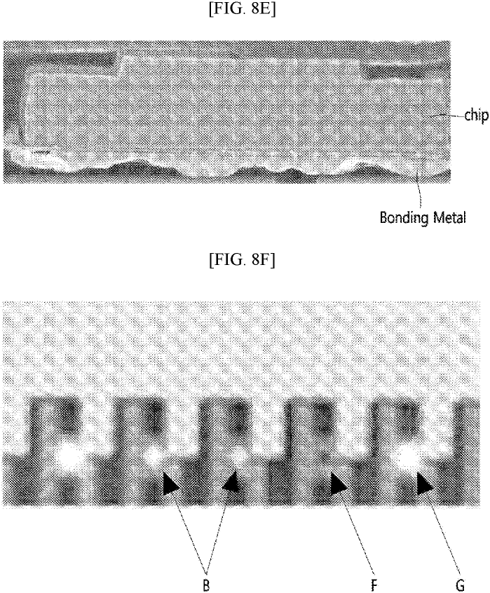

Next, FIGS. 8A to 8B are diagrams illustrating self-assembly in the display device 300 according to the internal technology, and FIG. 8C is a picture of self-assembly in the display device according to the internal technology.

In the display device 300 according to the internal technology, either the first assembly electrode 201 or the second assembly electrode 202 is brought into contact with the bonding metal 155 of the semiconductor light emitting device 150 through a bonding process.

However, in order to solve the problem that the bonding area is also reduced as the semiconductor light emitting device 150 is miniaturized, as shown in FIGS. 8A to 8B, a method of omitting the existing Vdd line and completely opening its role to one side of the electrode wiring is used.

However, when this method is used, the semiconductor light emitting device 150 drawn to the first assembly electrode 201 by DEP in the fluid comes into contact with the first assembly electrode 201 and becomes conductive. Accordingly, the electric field force is concentrated on the second assembly electrode 202 that is not opened by the insulating layer 212, and as a result, there is a problem in that the assembly is biased in one direction.

Referring to FIGS. 8B and 8C, the contact area C between the bonding metal 155 of the semiconductor light emitting device 150 and the first assembly electrode 201 functioning as a panel electrode is very small, so poor contact can be occurred.

For example, according to the undisclosed internal technology, DEP Force is required for self-assembly, due to the difficulty of uniform control of the DEP force, there is a problem in that the semiconductor light emitting device tilts to a different place in the assembly hole during assembly using self-assembly.

In addition, due to this tilt phenomenon of the semiconductor light emitting device, electrical contact characteristics are lowered in the subsequent electrical contact process, resulting in a defective lighting rate and a lower yield.

Therefore, according to the unpublished internal technology, DEP Force is required for self-assembly, but when using the DEP Force, the semiconductor light emitting device faces a technical contradiction in which electrical contact characteristics are reduced due to the tilt phenomenon.

Next, FIG. 8D is a diagram illustrating a tilt phenomenon that can occur during self-assembly according to an internal technology, and FIG. 8E is a picture of self-assembly in a display device according to an internal technology.

According to internal description, an insulating layer 212 is disposed on the first and second assembly electrodes 201 and 202 on the assembly substrate 200, self-assembly by the dielectrophoretic force of the semiconductor light emitting device 150 was performed in the assembly hole 220H set by the assembly and assembly barrier wall 207. However, according to internal technology, the electric field force is concentrated to the second assembly electrode 202, and as a result, there is a problem in that the assembly is biased in one direction, and thus the problem of self-assembly is not properly performed and the problem of tilt in the assembly hole 220H has been studied.

Further, FIG. 8E is a FIB (focused ion beam) photograph of a light emitting device (chip) and bonding metal in a display panel according to an internal technology, and FIG. 8F is lighting data in a display panel in an internal technology.

As shown in FIG. 8E, in the semiconductor light emitting device according to the internal technology, the surface morphology of the back bonding metal is not good, and the contact characteristics between the back bonding metal of the light emitting device and the panel wiring are not good, so lighting failure occurs.

In addition, according to the internal technology, the back bonding metal is in direct contact with the assembly electrode, but electrical contact failure occurs due to the non-uniformity of the surface of the bonding metal.

For example, FIG. 8F is lighting data in a display panel according to an internal technology.

According to internal technology, in the self-assembly method, weak lighting (B: Bad) or not lighting (F: Fail) occurs due to tilting due to non-uniformity of DEP force, or a defect in the surface characteristics of the rear bonding metal, and good lighting (G: Good) was not achieved, and the lighting rate was studied at a level of 93.94%.

In the internal technology, for the electrode layer of the light emitting device, a material such as Ti, Cu, Pt, Ag, Au is used. When a bonding metal made of a material such as Sn or In is formed on the electrode layer made of such a material, the surface becomes uneven due to aggregation or the like.

On the other hand, in the internal technology, the deposition rate was increased to improve the surface properties of the bonding metal, but even if the agglomeration phenomenon was partially alleviated, another problem was found that the grain size decreased as the deposition rate increased and the contact force decreased, the problem of improving the surface properties of the bonding metal was not easy.

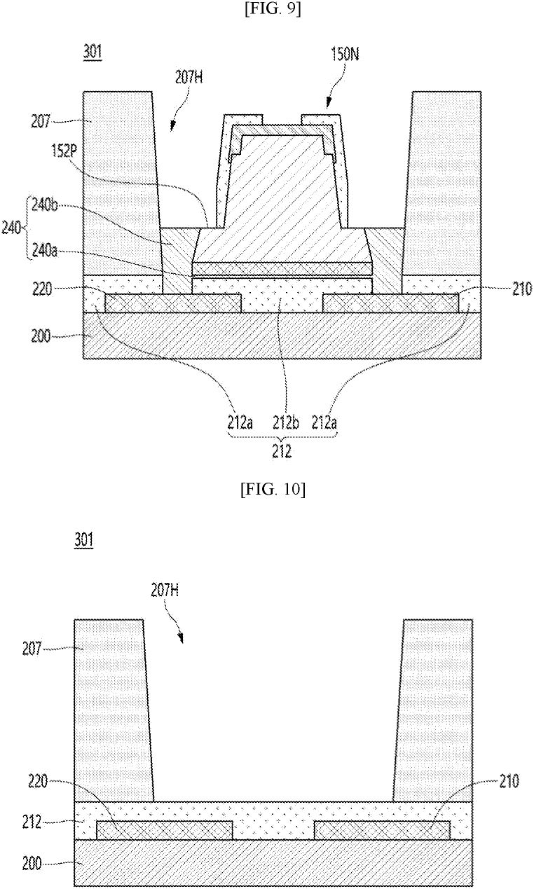

Next, a display device 301 including a semiconductor light emitting device according to an embodiment will be described with reference to FIGS. 9 to 19.

FIG. 9 is a cross-sectional view of a display device 301 including a semiconductor light emitting device according to an embodiment.

One of the technical problems of the embodiment is to solve the problem of electrical contact in the panel wiring process for electrically connecting the assembly electrode and the semiconductor light emitting device.

In addition, one of the technical problems of the embodiment is to solve the problem of low self-assembly rate due to non-uniformity of DEP force in the self-assembly method using dielectrophoresis (DEP).

In addition, one of the technical problems of the embodiment is that as the distribution of DEP Force is strongly formed not only inside the assembly hole but also on the upper side of the assembly hole, to solve the problem of a screening effect, in which a semiconductor light emitting device to be assembled cannot enter an assembly hole because a semiconductor light emitting device that is not an assembly target blocks the entrance to the assembly hole.

Referring to FIG. 9, a display device 301 can include a semiconductor light emitting device according to an embodiment can include a substrate 200, a first assembly electrode 210, a second assembly electrode 220, and an insulating layer 212, an assembly barrier wall 207, a plating layer 240, and a semiconductor light emitting device 150.

The display device 301 including the semiconductor light emitting device according to the embodiment can include a substrate 200, a first assembly electrode 210, a second assembly electrode 220 spaced apart from each other on the substrate 200, an insulating layer 212 disposed on the first assembly electrode 210 and the second assembly electrode 220, and an assembly barrier wall 207 including a predetermined assembly hole 207H and disposed on the insulating layer 212, a plating layer 240 electrically connected to the first assembly electrode 210 and the second assembly electrode 220, and the semiconductor light emitting device 150 disposed in the assembly hole 207H and electrically connected to the first assembly electrode 210 and the second assembly electrode 220 by the plating layer 240.

The insulating layer 212 can include a center insulating layer 212c disposed on a bottom surface of the semiconductor light emitting device 150 and an edge insulating layer 212a disposed spaced apart from both sides of the center insulating layer 212c.

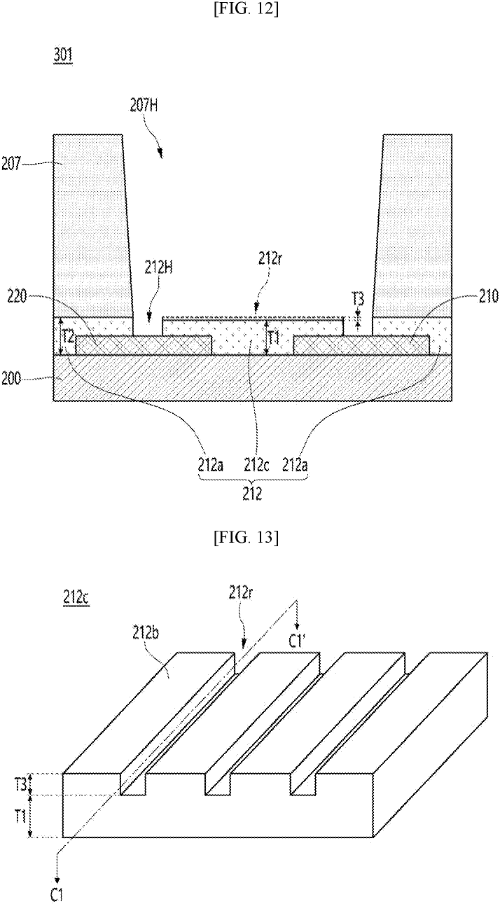

The center insulating layer 212c can include a recess 212r (refer to FIG. 12) of the insulating layer, and a first thickness T1 of the center insulating layer 212c can be smaller than a second thickness T2 of the edge insulating layer 212a.

The plating layer 240 can include a first plating layer 240a disposed between the bottom surface of the semiconductor light emitting device 150 and the center insulating layer 212c and a second plating layer 240b disposed between the side surface of the semiconductor light emitting device 150 and the first and second assembly electrodes 210 and 220.

The first plating layer 240a can also be disposed in the recess 212r of the insulating layer of the center insulating layer 212c.

One end of the second plating layer 240b can be in contact with upper surfaces of the first and second assembly electrodes 210 and 220 exposed by the center insulating layer 212c and the edge insulating layer 212a.

In addition, another end of the second plating layer 240b can be in contact with the first plating layer 240a and can be in contact with a side surface of the semiconductor light emitting device 150.

According to the display device of the semiconductor light emitting device according to the embodiment, by providing a plating layer 240 electrically connecting the first assembly electrode 210, the second assembly electrode 220 and the semiconductor light emitting device 150, there is a technical effect that can solve the problem of electrical contact in the panel wiring process for electrically connecting the assembly electrode and the semiconductor light emitting device.

For example, in the embodiment, the insulating layer 212 disposed on the first and second assembly electrodes 210 and 220 can include a center insulating layer 212c disposed on the bottom surface of the semiconductor light emitting device 150 and an edge insulating layer 212a disposed spaced apart from both sides of the center insulating layer 212c, and the center insulating layer 212c can include a recess 212r in the insulating layer.

At this time, the plating layer 240 electrically connecting the first assembly electrode 210, the second assembly electrode 220 and the semiconductor light emitting device 150 can include a first plating layer 240a disposed between the bottom surface of the semiconductor light emitting device 150 and the center insulating layer 212c and a second plating layer 240b disposed between the side surface of the semiconductor light emitting device 150 and the first and second assembly electrodes 210 and 220.

The second plating layer 240b is in contact with the top surfaces of the first and second assembly electrodes 210 and 220 exposed by the center insulating layer 212c and the edge insulating layer 212a, and the first plating layer 240a can also be disposed in the recess 212r of the insulating layer of the center insulating layer 212c.

According to the embodiment, the plating layer 240 can include the second plating layer 240b disposed between the side surface of the semiconductor light emitting device 150 and the first and second assembly electrodes 210 and 220, can improve the electrical reliability by improving the electrical contact performance in the panel wiring process that electrically connects the assembly electrode and the semiconductor light emitting device.

Accordingly, according to the embodiment, it is possible to reduce assembly defects by removing solder from the bottom surface of the semiconductor light emitting device chip in the internal technology, and it is possible to prevent the light emitting device chip from being separated during the metal contact process.

In addition, according to the embodiment, the plating layer 240 can include a first plating layer 240a that is also disposed between the bottom surface of the semiconductor light emitting device 150 and the center insulating layer 212c, and power can be evenly applied to the entire bottom surface of the semiconductor light emitting device 150, so that there is a special technical effect that can significantly improve the luminance of the display.

Hereinafter, the technical features of the present invention will be described in more detail with reference to FIGS. 10 to 19.

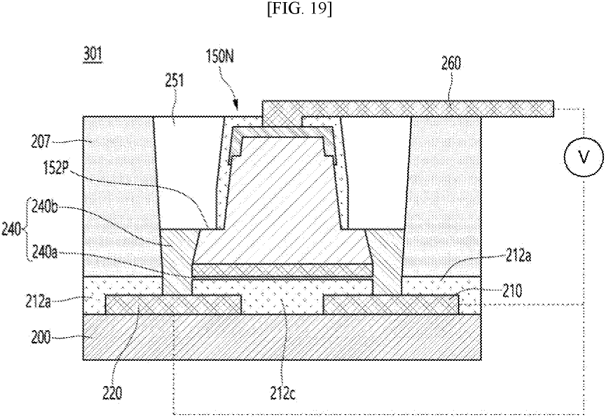

FIGS. 10 to 18 are cross-sectional views of a manufacturing process of a display device 301 including a semiconductor light emitting device according to an embodiment. FIG. 19 is a cross-sectional view of a display device 301 including a semiconductor light emitting device according to an embodiment.

Referring to FIG. 10, a display device 301 can include a semiconductor light emitting device according to an embodiment can include an assembly substrate 200, a first assembly electrode 210, a second assembly electrode 220, an insulating layer 212, an assembly barrier wall 207, and an assembly hole 207H.

The assembly substrate 200 can include a pair of first assembly electrodes 210 and second assembly electrodes 220 corresponding to each of the semiconductor light emitting devices 150N to be assembled. The first assembly electrode 210 and the second assembly electrode 220 can be formed by stacking a single metal, a metal alloy, or a metal oxide in multiple layers. For example, the first assembly electrode 210 and the second assembly electrode 220 can be formed including at least one of Cu, Ag, Ni, Cr, Ti, Al, Rh, Pd, Ir, Ru, Mg, Zn, Pt, Au, or Hf, but is not limited thereto.

In addition, the first assembly electrode 210 and the second assembly electrode 220 can be formed including at least one of indium tin oxide (ITO), indium zinc oxide (IZO), indium zinc tin oxide (IZTO), indium aluminum zinc oxide (IAZO), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), IGZO (In—Ga ZnO), ZnO, IrOx, RuOx, NiO, RuOx/ITO, Ni/IrOx/Au, or Ni/IrOx/Au/ITO, and is not limited thereto.

As the first assembly electrode 210, the second assembly electrode 220 emits an electric field as an AC voltage is applied, the semiconductor light emitting device 150N inserted into the assembly hole 207H can be fixed by dielectrophoretic force. A distance between the first assembly electrode 210 and the second assembly electrode 220 can be smaller than a width of the semiconductor light emitting device 150N and a width of the assembly hole 207H, the assembly position of the semiconductor light emitting device 150N using the electric field can be more precisely fixed.

An insulating layer 212 is formed on the first assembly electrode 210 and the second assembly electrode 220 to protect the first assembly electrode 210 and the second assembly electrode 220 from the fluid 1200 and leakage of current flowing through the first assembly electrode 210 and the second assembly electrode 220 can be prevented. For example, the insulating layer 212 can be formed of a single layer or multiple layers of an inorganic insulator such as silica or alumina or an organic insulator. The insulating layer 212 can have a minimum thickness to prevent damage to the first assembly electrode 210 and the second assembly electrode 220 when the semiconductor light emitting device 150N is assembled, and it can have a maximum thickness for the semiconductor light emitting device 150N being stably assembled.

A barrier wall 207 can be formed on the insulating layer 212. A portion of the barrier wall 207 can be positioned on the first assembly electrode 210 and the second assembly electrode 220, and the remaining region can be positioned on the assembly substrate 200.

On the other hand, when the assembly substrate 200 is manufactured, a portion of the barrier walls formed on the entire upper portion of the insulating layer 212 is removed, an assembly hole 207H in which each of the semiconductor light emitting devices 150N is combined and assembled to the assembly substrate 200 can be formed.

An assembly hole 207H to which the semiconductor light emitting devices 150N are coupled is formed in the assembly substrate 200, and a surface on which the assembly hole 207H is formed can be in contact with the fluid. The assembly hole 207H can guide an accurate assembly position of the semiconductor light emitting device 150N.

Meanwhile, the assembly hole 207H can have a shape and a size corresponding to the shape of the semiconductor light emitting device 150N to be assembled at a corresponding position. Accordingly, it is possible to prevent assembling other semiconductor light emitting devices or assembling a plurality of semiconductor light emitting devices in the assembly hole 207H.

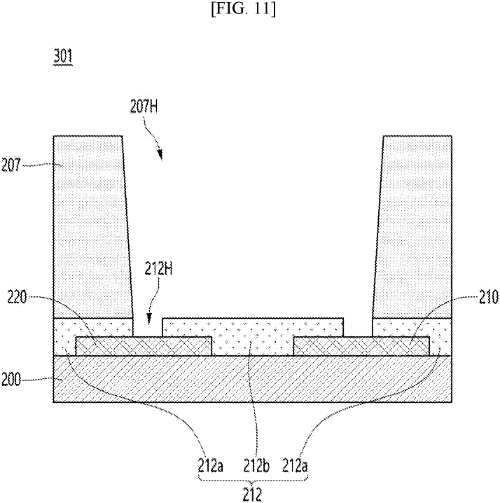

Next, referring to FIG. 11, a portion of the insulating layer 212 can be removed to form an insulating layer hole 212H exposing top surfaces of the first and second assembly electrodes 210 and 220.

Through this, the insulating layer 212 can include a center preliminary insulating layer 212b disposed on the bottom surface of the semiconductor light emitting device 150 and an edge insulating layer 212a spaced apart from both sides of the center preliminary insulating layer 212b.

Next, referring to FIG. 12, the center insulating layer 212c can be formed by partially etching the center preliminary insulating layer 212b to form a recess 212r of the insulating layer having a third thickness T3.

As the recess 212r of the insulating layer is formed, the first thickness T1 of the center insulating layer 212c can be smaller than the second thickness T2 of the edge insulating layer 212a.

FIG. 13 is a perspective view of the center insulating layer 212c in the embodiment. The center insulating layer 212c in FIG. 12 can be a cross-sectional view taken along line C1-C1′ in FIG. 13.

The center insulating layer 212c can be formed by forming a recess 212r of the insulating layer with respect to the center preliminary insulating layer 212b.

The recess 212r of the insulating layer can include a trench having a polygonal shape such as a quadrangle or a triangle. In addition, the recess 212r of the insulating layer can include a curvature recess such as a semi-circular shape or a semi-elliptical shape.

According to the embodiment, in the subsequent plating layer forming process, a gap is formed between the bottom surface of the semiconductor light emitting device 150 and the center insulating layer 212c through the recess 212r of the center insulating layer 212c, so the first plating layer 240a can be efficiently formed. Accordingly, power can be evenly applied to the entire bottom surface of the semiconductor light emitting device 150, and there is a special technical effect of remarkably improving the luminance of the display.

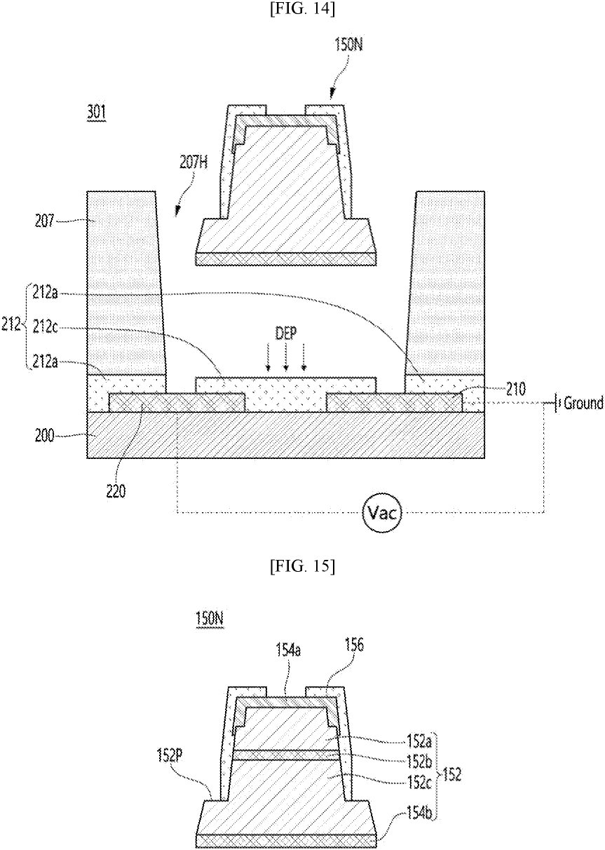

Next, referring to FIG. 14, the semiconductor light emitting device 150N can be put into a chamber filled with a fluid, and the semiconductor light emitting device 150N can move to the assembly substrate 200 by a magnetic field generated from the assembly device having a predetermined magnetism.

At this time, the light emitting device 150N adjacent to the assembly hole 207H of the assembly substrate 200 can be assembled into the assembly hole by DEP force due to the electric field of the first and second assembly electrodes 210 and 220.

Next, FIG. 15 is a cross-sectional view of the semiconductor light emitting device 150 in the embodiment, and the semiconductor light emitting device 150N can be implemented as a vertical semiconductor light emitting device as shown, but is not limited thereto, and a horizontal light emitting device can be employed.

The semiconductor light emitting device 150N can include a first conductivity type semiconductor layer 152a, a second conductivity type semiconductor layer 152c, and an active layer 152b disposed between the second conductivity type semiconductor layer 152c, and the active layer 152b. The first conductivity type semiconductor layer 152a can be an n-type semiconductor layer, and the second conductivity type semiconductor layer 152c can be a p-type semiconductor layer, but is not limited thereto.

A first electrode layer 154a can be disposed on the first conductivity type semiconductor layer 152a, and a second electrode layer 154b can be disposed on the second conductivity type semiconductor layer 152c. To this end, a partial region of the first conductivity type semiconductor layer 152a or the second conductivity type semiconductor layer 152c can be exposed to the outside.

The semiconductor light emitting device 150N can include a magnetic layer having a magnetic material. The magnetic layer can include a metal having magnetism, such as nickel (Ni). Since the semiconductor light emitting device 150N injected into the fluid can include a magnetic layer, it can move to the assembly substrate 200 by a magnetic field generated from the assembly device. The magnetic layer can be disposed above or below or on both sides of the light emitting device.

The semiconductor light emitting device 150N can include a passivation layer 156 surrounding the upper and side surfaces. The passivation layer 156 can be formed by using an inorganic insulator such as silica or alumina through PECVD, LPCVD, sputtering deposition, or the like. After the semiconductor light emitting device 150N is assembled on the assembly substrate 200, in the manufacturing process of the display device, a portion of the passivation layer 156 can be etched.

The semiconductor light emitting device 150N according to the embodiment can include a protruding semiconductor layer 152P. For example, in the semiconductor light emitting device 150N, a portion of a side surface of the second conductivity type semiconductor layer 152c can protrude laterally than the first conductivity type semiconductor layer 152a.

In addition, the passivation layer 156 can be exposed without being formed on the protruding semiconductor layer 152P.

According to the embodiment, since the lower side of the semiconductor light emitting device 150 receives more DEP force by the protruding semiconductor layer 152P, there is a special technical effect of controlling the vertical direction of the semiconductor light emitting device 150.

For example, when the semiconductor light emitting device 150N is a vertical light emitting device, the orientation of the first conductivity type semiconductor layer 152a and the second conductivity type semiconductor layer 152c is important in electrical connection with the assembly electrodes 210 and 220.

In the related art, when the semiconductor light emitting device 150N is a vertical light emitting device, it is difficult to control the directionality of the first conductivity type semiconductor layer 152a and the second conductivity type semiconductor layer 152c. However, according to the embodiment, since the semiconductor light emitting device has the protruding semiconductor layer 152P and a higher DEP force can be applied to the protruding semiconductor layer 152P, there is a special technical effect of controlling the direction of the second conductivity type semiconductor layer 152c to the direction of the assembly electrodes 210 and 220.

Referring back to FIG. 14, in relation to the method of applying an assembly signal to the first assembly electrode 210 and the second assembly electrode 220 in the embodiment, an AC signal can be applied to the first assembly electrode 210 and the second assembly electrode 220. At this time, a V+/V- signal can be applied to the second assembly electrode 220, and the first assembly electrode 210 can be grounded.

In the embodiment, as the first assembly electrode 210 is grounded and V+/V can be applied to the second assembly electrode 220 to prevent a voltage drop, there is a special technical effect that can maintain high assembly force.

In addition, according to the grounding of the first assembly electrode 210 in the embodiment, there is a special technical effect for minimizing the effect of attaching the semiconductor light emitting device to the barrier wall by acting as an electric field shielding in an area other than the assembly area.

For example, according to the embodiment, the distribution of DEP Force can be strongly and uniformly distributed at the inner center of the assembly hole through electric field shielding on the upper side of the assembly hole, and the distribution strength can be controlled weakly on the upper side of the assembly hole. Through this, a semiconductor light emitting device that is not an assembly target cannot be located on the upper side of the assembly hole, so the entrance to the assembly hole cannot be blocked, and there is a special technology effect that can solve the problem of the screening effect in which the semiconductor light emitting device to be assembled cannot enter the assembly hole.

According to the electric field (E field) gradient distribution to which the embodiment is applied, the E field (log scale) on the upper side of the assembly hole of the assembly barrier wall 207 is about 6 (based on log scale), and it is about lower about 1,000 times to 10,000 times compared to other internal technologies.

Therefore, according to the embodiment, as the V+/V- signal is applied to the second assembly electrode 220, and the first assembly electrode 210 is grounded, an assembly electrode structure having an electrical shielding effect can be implemented. Accordingly, the E field gradient around the assembly barrier wall is small so that the distribution of the DEP force is strongly and uniformly distributed in the center of the assembly hole, and the strength of the distribution can be controlled weakly on the upper side of the assembly hole.

In the end, according to the embodiment, the semiconductor light emitting device, which is not an assembly target, is not located on the upper side of the assembly hole to prevent blocking the entrance to the assembly hole, and there is a special technical effect that can significantly increase the assembly yield by concentrating the DEP force uniformly on the assembly hole to be assembled, thereby solving the problem of the screening effect that the semiconductor light emitting device to be assembled cannot enter the assembly hole.

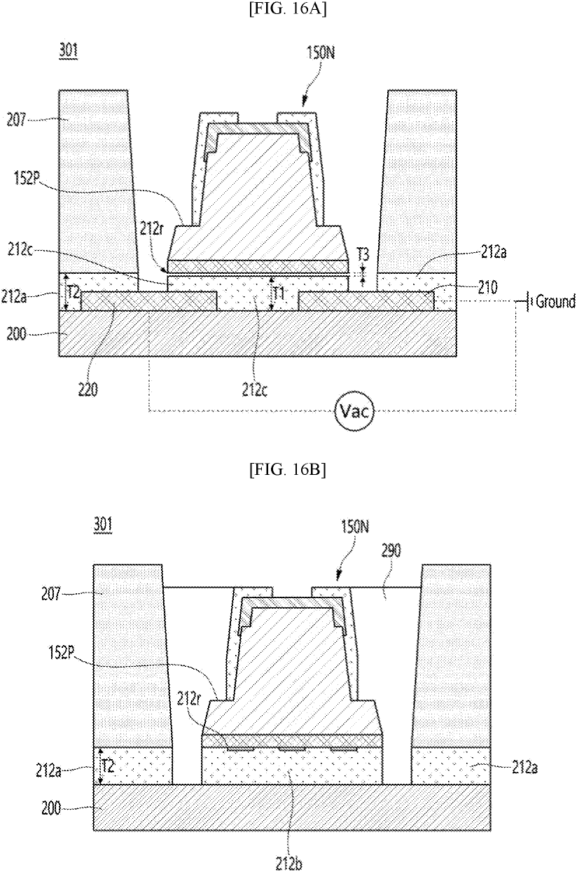

Next, referring to FIG. 16A, the semiconductor light emitting device 150N can be positioned on the center insulating layer 212c of the assembly hole 207H.

As described above, FIG. 13 is a perspective view of the center insulating layer 212c in the embodiment. The center insulating layer 212c in FIG. 16A can be a cross-sectional view taken along line C1-C1′ in FIG. 13.

Meanwhile, 16b can be a cross-sectional view taken along a line perpendicular to the line C1-C1′ in FIG. 13.

Referring to FIG. 16B, a photoresist film 290 can be used for fixing on the insulating layer of the semiconductor light emitting device 150N during the plating process. For example, a predetermined photoresist film 290 can be spray coated on the semiconductor light emitting device 150N disposed on the center preliminary insulating layer 212b, and through patterning. And the photosensitive film 290 in the region where the first and second assembly electrodes 210 and 220 is located as shown in FIG. 16A can be developed and removed, and the photoresist film 290 in the region where the first and second assembly electrodes 210 and 220 is not present can remain to fix the semiconductor light emitting device 150N as shown in FIG. 16B.

The photoresist film 290 can be a negative PR, but is not limited thereto.

Referring back to FIG. 16A, in the embodiment, the insulating layer 212 disposed on the first and second assembly electrodes 210, 220 can include a center insulating layer 212c disposed on the bottom surface of the semiconductor light emitting device 150 and an edge insulating layer 212a spaced apart from both sides of the center insulating layer 212c, and the center insulating layer 212c can include a recess 212r of the insulating layer.

Further, unlike shown in FIG. 16A, a partial region of the semiconductor light emitting device 150N can be spaced apart from the center insulating layer 212c by the recess 212r of the insulating layer, but the remaining region can maintain a state in contact with the center preliminary insulating layer 212b.

The recess 212r of the insulating layer can include a trench having a polygonal shape such as a quadrangle or a triangle, or a curvature recess such as a semicircle or a semi-ellipse.

The photoresist film 290 shown in FIG. 16B can be removed so that the inlet of the recess 212r of the insulating layer is not located.

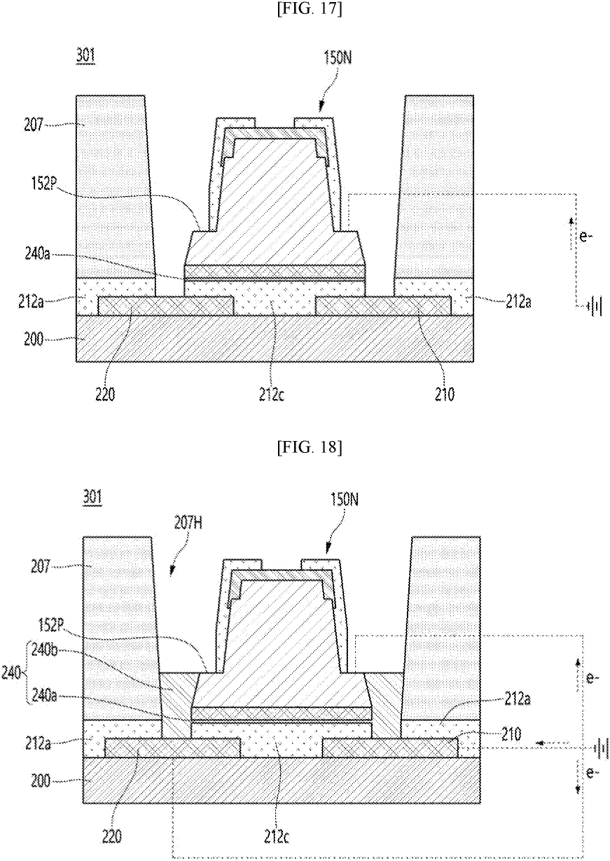

Next, referring to FIG. 17, according to the embodiment, since the plating layer 240 can include a first plating layer 240a that is also disposed between the bottom surface of the semiconductor light emitting device 150 and the center insulating layer 212c, power can be evenly applied to the entire bottom surface of the semiconductor light emitting device 150. So, there is a special technical effect that can significantly improve the luminance of the display.

The first plating layer 240a can include SnAg or Cu plating, but is not limited thereto.

In the first plating layer 240a forming process in the embodiment, by applying a predetermined negative power to the protruding semiconductor layer 152P, there is a special technical effect that the first plating layer 240a can be efficiently plated between the bottom surface of the semiconductor light emitting device 150 and the center insulating layer 212c.

The first plating layer 240a can also be disposed in the recess 212r of the insulating layer of the center insulating layer 212c.

According to internal research, there was a technical difficulty in forming a plating layer between the semiconductor light emitting device 150N and the insulating layer of the center insulating layer 212c.

For example, when plating is performed while negative power is applied only to the first and second assembly electrodes 210 and 220, as the plating layer is formed and expanded from the first and second assembly electrodes 210 and 220, the entrance between the semiconductor light emitting device 150N and the insulating layer of the center insulating layer 212c is blocked, so the plating layer was not formed smoothly.

However, in the embodiment, when a predetermined negative power is applied to the protruding semiconductor layer 152P, and the second electrode layer 154b of the semiconductor light emitting device 150N functions as a seed layer, and there is a special technical effect that the first plating layer 240a can be effectively plated between the bottom surface of the semiconductor light emitting device 150 and the center insulating layer 212c.

In addition, according to the embodiment, the first plating layer 240a can be formed on the protruding semiconductor layer 152P, and through this, the subsequent forming process of the second plating layer 240b can proceed more smoothly.

According to the embodiment, the first plating layer 240a forming process proceeds through the recess 212r of the insulating layer of the center insulating layer 212c, a first plating layer 240a can be efficiently formed between the bottom surface of the semiconductor light emitting device 150 and the center insulating layer 212c, so power can be evenly applied to the entire bottom surface of the semiconductor light emitting device 150. Therefore, there is a special technical effect that can significantly improve the luminance of the display.

Next, referring to FIG. 18, the second plating layer 240b can be formed by applying negative power to the first and second assembly electrodes 210 and 220 as well.

The second plating layer 240b can be in contact with upper surfaces of the first and second assembly electrodes 210 and 220 exposed by the center insulating layer 212c and the edge insulating layer 212a.

Accordingly, the plating layer 240 electrically connecting the first assembly electrode 210, the second assembly electrode 220 and the semiconductor light emitting device 150 can include a first plating layer 240a disposed between a bottom surface of the semiconductor light emitting device 150 and the center insulating layer 212c, and a second plating layer 240b disposed between the side surface of the semiconductor light emitting device 150 and the first and second assembly electrodes 210 and 220.

According to the embodiment, the plating layer 240 can include a second plating layer 240b disposed between the side surface of the semiconductor light emitting device 150 and the first and second assembly electrodes 210 and 220, can improve the electrical reliability by improving the electrical contact performance in the panel wiring process that electrically connects the assembly electrode and the semiconductor light emitting device.

Accordingly, according to the embodiment, it is possible to reduce the assembly defect by removing the solder on the bottom surface of the semiconductor light emitting device chip in the internal technology, and it is possible to prevent separation of the light emitting device chip that can occur during the metal contact process.

In addition, according to the embodiment, the plating layer 240 can include a first plating layer 240a that is also disposed between the bottom surface of the semiconductor light emitting device 150 and the center insulating layer 212c, and power can be evenly applied to the entire bottom surface of the semiconductor light emitting device 150, so there is a special technical effect that can significantly improve the luminance of the display.

Next, FIG. 19 is a cross-sectional view of the display device 301 of a semiconductor light emitting device.

Referring to FIG. 19, after the photosensitive film 290 shown in FIG. 16B is removed, a predetermined light-transmitting resin 251 can be filled in the assembly hole 207H, and a second panel wiring 260 electrically connected to the semiconductor light emitting device 150N can be formed.

According to the semiconductor light emitting device display device according to the embodiment, the plating layer 240 electrically connecting the assembly electrode and the semiconductor light emitting device can include a second plating layer 240b disposed on the side surface of the semiconductor light emitting device 150 and between the first and second assembly electrodes 210, 220. Accordingly, electrical reliability can be improved by improving electrical contact performance in a panel wiring process for electrically connecting the assembly electrode and the semiconductor light emitting device.

Accordingly, according to the embodiment, it is possible to reduce the assembly defect by removing the solder on the bottom surface of the semiconductor light emitting device chip in the internal technology, and it is possible to prevent separation of the light emitting device chip that can occur during the metal contact process.

In addition, according to the embodiment, the plating layer 240 can include a first plating layer 240a that is also disposed between the bottom surface of the semiconductor light emitting device 150 and the center insulating layer 212c, and power can be evenly applied to the entire bottom surface of the semiconductor light emitting device 150. So, there is a special technical effect that can significantly improve the luminance of the display.

Further, according to the embodiment, since the lower side of the semiconductor light emitting device 150 receives more DEP force by the protruding semiconductor layer 152P, there is a special technical effect of controlling the vertical direction of the semiconductor light emitting device 150.

In addition, according to the embodiment, there is a technical effect that can solve the problem of low self-assembly rate due to the non-uniformity of the DEP force in the self-assembly method using dielectrophoresis (DEP).

In addition, according to the embodiment, the semiconductor light emitting device, which is not an assembly target, is not located on the upper side of the assembly hole to prevent blocking the entrance to the assembly hole, and there is a special technical effect that can significantly increase the assembly yield by concentrating the DEP force uniformly on the assembly hole to be assembled by solving the problem of the screening effect that the semiconductor light emitting device to be assembled cannot enter the assembly hole.

The above detailed description should not be construed as restrictive in all respects and should be considered as exemplary. The scope of the embodiments should be determined by a reasonable interpretation of the appended claims, and all modifications within the equivalent scope of the embodiments are included in the scope of the embodiments.

The embodiment can be applied to a display field for displaying images or information.

The embodiment can be applied to a display field for displaying images or information using a semiconductor light emitting device.

The embodiment can be applied to a display field for displaying images or information using a micro-level or nano-level semiconductor light emitting device.

What is claimed is:

1. A display device comprising:
a substrate;
a first assembly electrode and a second assembly electrode spaced apart and disposed on the substrate;
an insulating layer disposed on the first assembly electrode and the second assembly electrode;
an assembly barrier wall comprising an assembly hole and disposed on the insulating layer;
a plating layer electrically connected to the first assembly electrode and the second assembly electrode; and
a semiconductor light emitting device disposed in the assembly hole and electrically connected to the first assembly electrode and the second assembly electrode by the plating layer.

2. The display device according to claim 1, wherein the insulating layer comprises a center insulating layer disposed on a bottom surface of the semiconductor light emitting device and an edge insulating layer disposed spaced apart in opposite sides of the center insulating layer.

3. The display device according to claim 1, wherein the center insulating layer comprises a recess of the insulating layer and a first thickness of the center insulating layer is smaller than a second thickness of the edge insulating layer.

4. The display device according to claim 3, wherein the plating layer comprises a first plating layer disposed between a bottom surface of the semiconductor light emitting device and the center insulating layer and a second plating layer disposed between a side surface of the semiconductor light emitting device and the first and second assembly electrodes.

5. The display device according to claim 4, wherein the first plating layer is disposed in the recess of the center insulating layer.

6. The display device according to claim 4, wherein one end of the second plating layer is in contact with upper surfaces of the first and second assembly electrodes exposed by the center insulating layer and the edge insulating layer, and
wherein another end of the second plating layer is in contact with the first plating layer and is in contact with a side surface of the semiconductor light emitting device.

7. The display device according to claim 4, wherein the semiconductor light emitting device comprises a first conductivity type semiconductor layer, an active layer and a second conductivity type semiconductor layer sequentially arranged, and
wherein the semiconductor light emitting device includes a protruding semiconductor layer in which a side surface of the second conductivity type semiconductor layer extends laterally than the first conductivity type semiconductor layer.

8. The display device according to claim 7, wherein the first plating layer is also disposed on the protruding semiconductor layer.

9. A display device comprising:
a substrate;
a first assembly electrode and a second assembly electrode separated and disposed on the substrate;
an insulating layer disposed on the first assembly electrode and the second assembly electrode;
an assembly barrier wall comprising an assembly hole and disposed on the insulating layer;
a plating layer electrically connected to the first assembly electrode and the second assembly electrode; and
a semiconductor light emitting device disposed in the assembly hole and electrically connected to the first assembly electrode and the second assembly electrode by the plating layer,
wherein the semiconductor light emitting device comprises a first conductivity type semiconductor layer, an active layer and a second conductivity type semiconductor layer sequentially arranged, and
wherein the semiconductor light emitting device comprises a protruding semiconductor layer in which a side portion of the second conductivity type semiconductor layer extends laterally than the first conductivity type semiconductor layer.

10. The display device according to claim 9, wherein the plating layer comprises a first plating layer disposed between a bottom surface of the semiconductor light emitting device and the center insulating layer, and a second plating layer disposed between a side surface of the semiconductor light emitting device and the first and second assembly electrodes.

11. The display device according to claim 9, wherein the semiconductor light emitting device further comprises a passivation layer on lateral surfaces of the first conductivity type semiconductor layer, the active layer and the second conductivity type semiconductor layer, and
wherein an edge of the passivation layer ends at the protruding semiconductor layer.

12. A display device comprising:
a substrate;
a first assembly electrode and a second assembly electrode spaced apart and disposed on the substrate;
an insulating layer disposed on the first assembly electrode and the second assembly electrode, and including an insulation layer hole that exposes at least one of the first assembly electrode and the second assembly electrode;
an assembly barrier wall comprising an assembly hole and disposed on the insulating layer; and
a semiconductor light emitting device disposed in the assembly hole and electrically connected to the first assembly electrode and the second assembly electrode.

13. The display device according to claim 12, further comprising a plating layer electrically connected to the first assembly electrode and the second assembly electrode, and connecting the semiconductor light emitting device to the first assembly electrode and the second assembly electrode.

14. The display device according to claim 13, wherein the plating layer includes:
a first plating layer interposed between the semiconductor light emitting device and the insulating layer; and
a second plating layer in the insulation layer hole and connected to the semiconductor light emitting device and the first and second assembly electrodes.

15. The display device according to claim 14, wherein the semiconductor light emitting device includes a first conductivity type semiconductor layer, an active layer and a second conductivity type semiconductor layer stacked sequentially, and
wherein the second conductivity type semiconductor layer includes a protruding semiconductor layer that extends laterally further than the first conductivity type semiconductor layer.

16. The display device according to claim 15, wherein the second conductivity type semiconductor layer includes a step formed by the protruding semiconductor layer.

17. The display device according to claim 15, wherein the second plating layer covers a lateral surface of the protruding semiconductor layer of the second conductivity type semiconductor layer.

18. The display device according to claim 15, wherein the semiconductor light emitting device further comprises a passivation layer on lateral surfaces of the first conductivity type semiconductor layer, the active layer and the second conductivity type semiconductor layer,
wherein an edge of the passivation layer ends at the protruding semiconductor layer, and
wherein a surface of the protruding semiconductor layer, a surface of the second plating layer, and the edge of the passivation layer are aligned.

19. The display device according to claim 18, further comprising a light-transmitting resin between the assembly barrier wall and the semiconductor light emitting device, and extending to the surface of the protruding semiconductor layer.

20. The display device according to claim 12, wherein the insulating hole delineates the insulating layer into a center insulating layer corresponding to the semiconductor light emitting device and an edge insulating layer corresponding to the assembly barrier wall.
